(19) United States
(12) Patent Application Publication
(10) Pub. No.: US 2015/0230342 A1
(43) Pub. Date: Aug. 13, 2015

(54) NOVEL STRUCTURE ACHIEVING FINE THROUGH HOLE PITCH FOR INTEGRATED CIRCUIT SUBSTRATES

(71) Applicant: Apple Inc., Cupertino, CA (US)

(72) Inventors: Jun Chung Hsu, Cupertino, CA (US); Jun Zhai, San Jose, CA (US)

(73) Assignee: Apple Inc., Cupertino, CA (US)

(21) Appl. No.: 14/244,299

(22) Filed: Apr. 3, 2014

Related U.S. Application Data
(60) Provisional application No. 61/937,147, filed on Feb. 7, 2014.

(51) Int. Cl. H05K 3/00; H05K 1/11; H05K 1/03

(52) U.S. Cl. CPC H05K 3/0044; H05K 1/032; H05K 1/115

(57) ABSTRACT

In some embodiments, a carrier substrate for an integrated circuit may include a core, a first plurality of openings, and a first insulating material. The core may include a first surface and a second surface substantially opposing the first surface. The first plurality of openings may extend from the first surface to the second surface of the core. In some embodiments, the first insulating material may be applied to a surface of the first plurality of openings. In some embodiments, the first plurality of openings may include a first conductor extending through each of the first plurality of openings from the first surface to the second surface. In some embodiments, at least a first subset of the first plurality of openings may include a first charge and at least a second subset of the first plurality of openings may include a second charge. The first charge and the second charge may be different.

### PRIORITY CLAIM

This application claims priority to U.S. Provisional Patent Application No. 61/937,147 entitled “NOVEL STRUCTURE ACHIEVING FINE THROUGH HOLE PITCH FOR INTEGRATED CIRCUIT SUBSTRATES” to Hsu et al. filed on Feb. 7, 2014, all of which is incorporated by reference herein.

### BACKGROUND

1. Technical Field

The present invention relates to semiconductor packaging and methods for preparing integrated circuit substrates. More particularly, some embodiments disclosed herein relate to a systems and methods for inhibiting short circuits in integrated circuits.

2. Description of the Related Art

Substrates are the foundation of integrated circuit packaging and manifest the foremost critical factors in system performance with silicon nodes shrinking to 20 nm and beyond. Comprehensive substrate design becomes an integral part of silicon design which usually consists of two key elements in terms of signal integrity and power integrity performance. In fact, during the package co-design process, the IR drop modeling simulation and analysis is a routine task were well integrated into the substrate design flow. Power integrity considered in substrate design has first order effect on SSO/SSN (simultaneously switching noise output), core voltage stability, and silicon architecture for bump pin-out topology. Advance wafer node requires low power supply voltage, this reduces the chip's threshold for noise margin. Low threshold for noise margin makes the chip vulnerable to glitches and failure. Furthermore, it requires more transistors per die resulting in more power consumption. Increased power consumption may strain the chip power delivery network causing dynamic voltage drop.

At high speeds power and ground plane resonance is the key to successful power delivery. Resonance is a major cause of SSO noise and cross-talk. Conductor trace, resistance, inductance effect, capacitive parasitics are considered the key for substrate design. The interactions between signal, power, timing, EMI, and clock cannot be ignored. Power integrity can be simulated by packaging model for system level analysis. DC voltage is one of the most important criterions for system operation. One of the most important factors which impacts DC voltage and IR drop is conductivity (resistance) decided by number of power/ground vias and their location. Decoupling power/ground by implementing smaller PTH pitch and reducing loop inductance with shorter trace length are essential for achieving the best substrate design.

However, there is a design rule which constrains designers from adopting finer PTH pitch on substrate core material. The problem is designers could never use identical C4 bump pitch for the PTH routing when the bump pitch is less than 200 um. Designer is forced to offset the via from the buildup layer by connecting trace to the PTH (resistance trade-off) or use larger C4 pitch at specific location of bump map in order to deliver power directly from the silicon to the substrate BGA by stacking vias on the PTH. On the other hand, larger PTH pitch may limit the number of the PTHs in area which is far less than the bump count. Currently one design rule includes a minimum hole wall to wall distance of about 125 um. PTH pitch rule may be about 205 um (i.e., 80 um PTH diameter+125 um=205 um) as depicted in FIG. 2 in the example of 200 um core. PTH diameter capability is core thickness dependent. In general, PTH size/core thickness rules include 80 um/200 um, 75 um/150 um, and 70 um/100 um. The dotted circle depicts glass fiber stabbing into the conductor (PTH copper).

One of the problems of making finer PTH pitch for substrate manufacture is CAF (Conductive Anodic Filament) which increases the shorting risk when an integrated circuit (IC) package is exposed under certain harsh operating condition (e.g., electric current and moisture). Short circuits may occur when a power (+) and a ground (−) short between a first PTH to an adjacent second PTH. In general, risks of short circuits increase when PTH pitch is decreased. An open path 110 at the interface of glass fiber 120 and resin 130 forming a core 140 adjacent conductors 100 can result in electrochemical migration (e.g., as depicted in FIGS. 1-3). Many different factors may increase shorting risks including: poor drilling condition; poor control of succeeding chemical processes after drilling; a resin's desmear resistance forming a core; voids formed inside of a core between glass fiber and resin due to poor resin flow during hot press; poor raw material quality control for core making (e.g., hollow glass fibers); and poorly manufactured glass for making prepreg. Substrate vendors cannot resolve many of these problems due to many different industries involved in the manufacture of the substrates.

### SUMMARY

Embodiments described herein are directed towards providing a structure connecting bump to ball grid array (BGA) while inhibiting concerns directed towards conductive anodic filament (CAF). In some embodiments, a core plated through hole (PTH) may include copper conductors with insulating material (e.g., a resin) surrounding the conductor. Insulating material may function to seal any open path (for example, due to delamination). Glass fibers may be inhibited from contacting conductors such that electrochemical migration was inhibited. In some embodiments, insulated PTHs may be used to separate conductors with a different charge. This feature may allow PTH pitch reduction, allowing designers to maximize the PTH quantity to enhance power integrity and also simplify the trace routing without using additional traces for offset via connections. The loop inductance may be minimized accordingly. The die size might be reduced due to flexible bump map layout. The other merit is good reliability because of less via been stacked on PTH.

In some embodiments, a carrier substrate for an integrated circuit may include a core, a first plurality of openings, and a first insulating material. The core may include a first surface and a second surface substantially opposing the first surface. The first plurality of openings may extend from the first surface to the second surface of the core. In some embodiments, the first insulating material may be applied to a surface of the first plurality of openings. In some embodiments, the first plurality of openings may include a first conductor extending through each of the first plurality of openings from the first surface to the second surface. In some embodiments, at least a first subset of the first plurality of openings may include a first charge and at least a second subset of the first plurality of openings may include a second charge. The first charge and the second charge may be different.

In some embodiments, a method for forming a carrier substrate for an integrated circuit may include forming a first plurality of openings extending from a first surface to a second surface of a core. The method may include applying a first insulating material to the first or the second surface such that the first insulating material is positioned in the first plurality of openings. The method may include forming a second plurality of openings in the first insulating material positioned in the first plurality of openings. A first diameter of the first openings may be greater than a second diameter of the second openings.

### BRIEF DESCRIPTION OF THE DRAWINGS

The following detailed description makes reference to the accompanying drawings, which are now briefly described.

FIG. 1 depicts an embodiment of a representation of a boundary in a substrate between a conductor and a core wherein delamination has occurred.

FIGS. 2-3 depict an embodiment of a representation of a substrate without interior insulation wherein fibers within the core have penetrated conductors.

FIGS. 4-5 depict an embodiment of a representation of a substrate including insulation positioned around conductors between the core and conductors.

FIGS. 6A-B depict an embodiment of a representation of a substrate including insulation positioned around conductors between the core and conductors such that insulated conductors are positioned between conductors carrying different charges.

FIG. 7 depicts an embodiment of a method for forming a carrier substrate for an integrated circuit which inhibits degradation due to short circuits.

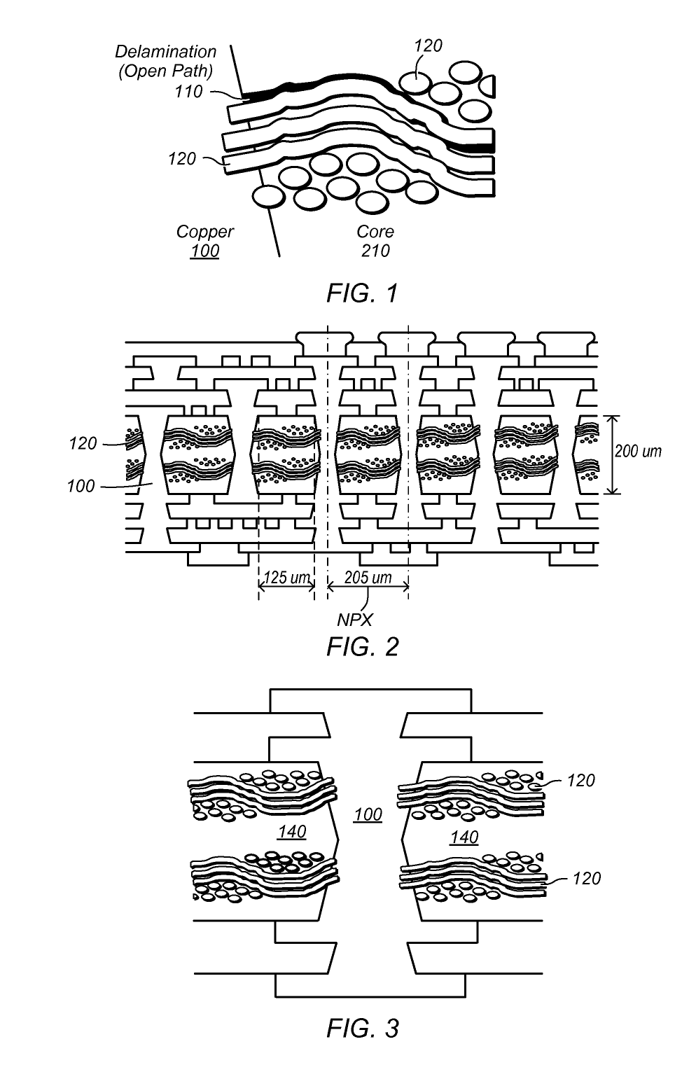

Specific embodiments are shown by way of example in the drawings and will be described herein in detail. It should be understood, however, that the drawings and detailed description are not intended to limit the claims to the particular embodiments disclosed, even where only a single embodiment is described with respect to a particular feature. On the contrary, the intention is to cover all modifications, equivalents and alternatives that would be apparent to a person skilled in the art having the benefit of this disclosure. Examples of features provided in the disclosure are intended to be illustrative rather than restrictive unless stated otherwise.

The headings used herein are for organizational purposes only and are not meant to be used to limit the scope of the description. As used throughout this application, the word “may” is used in a permissive sense (i.e., meaning having the potential to), rather than the mandatory sense (i.e., meaning must). The words “include,” “including,” and “includes” indicate open-ended relationships and therefore mean including, but not limited to. Similarly, the words “have,” “having,” and “has” also indicated open-ended relationships, and thus mean having, but not limited to. The terms “first,” “second,” “third,” and so forth as used herein are used as labels for nouns that they precede, and do not imply any type of ordering (e.g., spatial, temporal, logical, etc.) unless such an ordering is otherwise explicitly indicated. For example, a “third die electrically connected to the module substrate” does not preclude scenarios in which a “fourth die electrically connected to the module substrate” is connected prior to the third die, unless otherwise specified. Similarly, a “second” feature does not require that a “first” feature be implemented prior to the “second” feature, unless otherwise specified.

Various components may be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors may be configured to electrically connect a module to another module, even when the two modules are not connected). In some contexts, “configured to” may be a broad recitation of structure generally meaning “having circuitry that” performs the task or tasks during operation. As such, the component can be configured to perform the task even when the component is not currently on. In general, the circuitry that forms the structure corresponding to “configured to” may include hardware circuits.

Various components may be described as performing a task or tasks, for convenience in the description. Such descriptions should be interpreted as including the phrase “configured to.” Reciting a component that is configured to perform one or more tasks is expressly intended not to invoke 35 U.S.C. §112, paragraph six, interpretation for that component.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

### DETAILED DESCRIPTION OF EMBODIMENTS

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

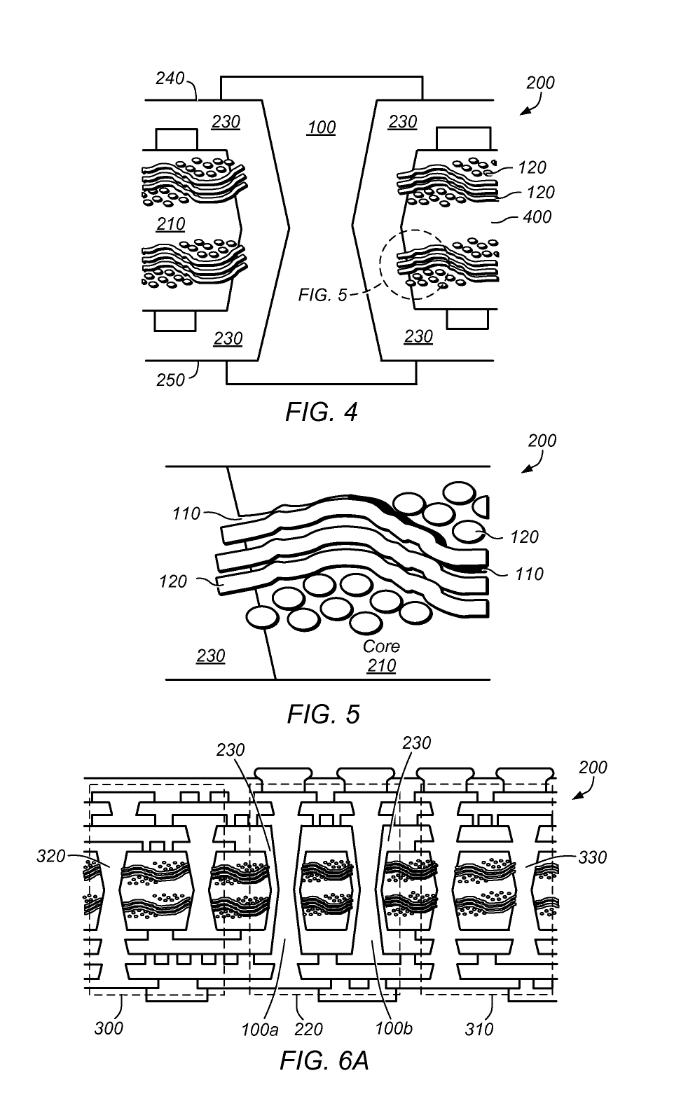

In some embodiments, a carrier substrate 200 for an integrated circuit may include a core 210, a first plurality of openings 220, and a first insulating material 230. FIGS. 4-5 depict an embodiment of a representation of a substrate 200 including insulation positioned around conductors between the core and conductors. The core may include a first surface 240 and a second surface 250 substantially opposing the first surface. In some embodiments, the core thickness may be equal to or less than about 200 micrometers. The first plurality of openings may extend from the first surface to the second surface of the core. The first plurality of openings may be formed in the core using, for example, drilling techniques (e.g., lasers). Other techniques may be used to form the first plurality of openings.

In some embodiments, the first insulating material may be applied to a surface of the first plurality of openings. In some embodiments, the first insulating material is applied to the surface of the first plurality of openings using vacuum lamination. Using vacuum lamination further ensures that the insulating material is pulled into the first plurality of openings especially due to the small nature of the openings. The insulating material may coat at least a portion of the surface of the openings. The first insulating material may include a resin.

In some embodiments, during application of the first insulating material the insulating material may essentially fill the openings. Filling the openings may ensure that the surfaces of the openings are coated adequately. In some embodiments, a second plurality of openings may be formed such as to reopen the first plurality of openings after the insulating material has been applied to the openings. The second plurality of openings may have a smaller diameter than the first plurality of openings to ensure that the insulating material is coating the surfaces of the first plurality of openings.

In some embodiments, the first/second plurality of openings may include a first conductor extending through each of the first plurality of openings from the first surface to the second surface. Conductors may be formed at least in part by copper. Conductors may function to convey electrical signals from the first surface to the second surface of the core. The conductors may function to convey electrical signals from electronic components coupled to the first surface to electronic components coupled to the second surface of the core.

The first insulating material may be positioned between the conductors and the core/surfaces of the first/second openings. The gap between core & glass fiber may be encapsulated by the insulating material. The insulating material may play a role as a sealant that may block an open path (e.g., due to delamination) in the core adjacent the first openings. Open paths may be sealed using the insulating material during installation of the insulating material in the first openings. In some embodiments, open paths may be sealed after installation of the insulating material in the first openings using the insulating material in that the insulating material may flow (e.g., especially at elevated temperatures during use) into open paths which formed during manufacture of the core and/or open paths which form later after production. The insulating material may inhibit glass fiber from contacting a conductor which may inhibit occurrence of electrochemical migration.

In some embodiments, the substrate may include at least one layer of insulating material applied to the first and/or second surface. In some embodiments, a layer of insulating material may be applied after the first conductor has been installed in the first openings. The substrate may include a third plurality of openings extending through the layer of insulating material. The substrate may include a second conductor extending through each of the third plurality of openings. At least some of the second conductors may be electrically coupled to one or more of the first conductors.

In some embodiments, additional layers of insulating material may be applied to the layer of insulating material as necessary. Openings may be formed in the additional layers of insulating material and conductors formed and/or positioned in the openings in the additional layers of insulating material. The additional conductors in the additional openings may be electrically coupled to the first and/or second conductors. The additional layers of insulating material and additional conductors may function together in order form at least a portion of an integrated circuit.

It is desirable to decrease PTH size to maximize the quantity of PTHs to enhance power integrity as well as simplifying trace routing without using additional tracing for offset via connection. Insulating conductors may require larger PTHs and so in spite of the benefits provided by the insulation, reducing the number of insulated conductors may increase the quantity of PTHs.

Towards this end PTHs may be grouped according to the net charge applied to the conductor positioned in the PTH. Conductors with equivalent net charges may be grouped together to inhibit short circuits. Conductors with equivalent charges should not short circuit across the conductors. Conductors may not have to be insulated as described herein if adjacent conductors have an equivalent net charge. In some embodiments, conductors which are adjacent conductors with different net charges may be insulated as described herein.

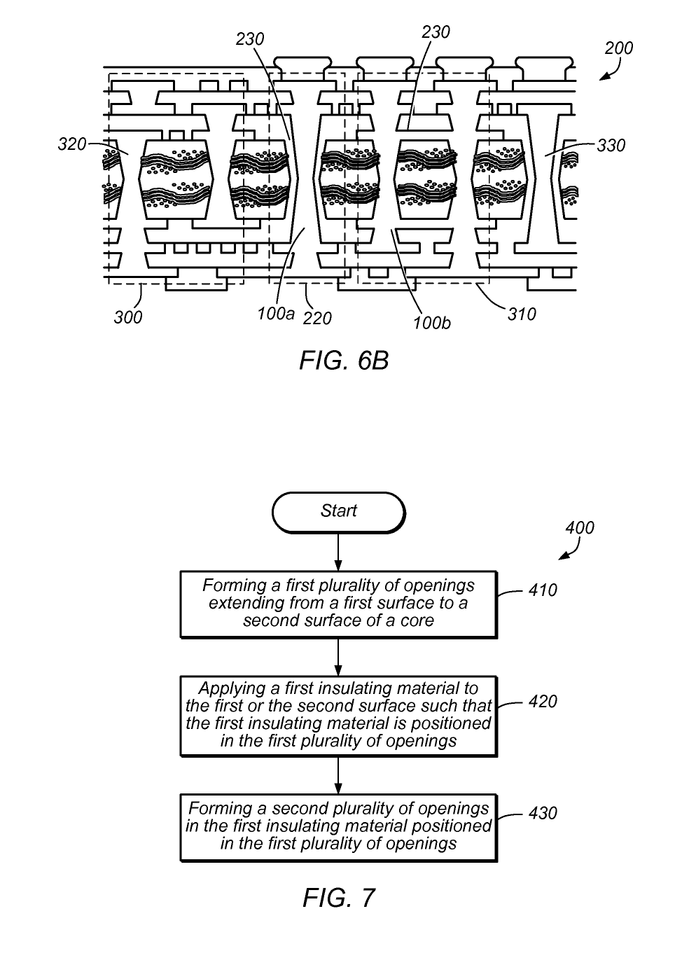

FIG. 6A depicts an embodiment of a representation of a substrate 200 including insulation 230 positioned around conductors 100 between the core and conductors such that insulated conductors are positioned between conductors carrying different charges. In some embodiments, at least a first subset 300 of the first plurality of openings may include a first charge applied to a third conductor 320 and at least a second subset 310 of the first plurality of openings may include a second charge applied to a fourth conductor 330. The first charge and the second charge may be different.

In some embodiments, the first plurality of openings 220 may be positioned between a third 300 and a fourth set 310 of openings extending from the first surface to the second surface of the core. The third conductor 320 may extend through each of the third plurality of openings and the fourth conductor 330 may extend through each of the fourth plurality of openings.

The first plurality of openings may be insulated because the conductors in the adjacent openings may have different net charges. Conductor 100a may have a different net charge than conductor 100b and as such include insulating material 230 surrounding both conductors to inhibit short circuits. As such conductors 100a may have an equivalent net charge as the adjacent uninsulated conductors 320. Conductors 100b may have an equivalent net charge as the adjacent uninsulated conductors 330. Therefore conductors with different net charges are separated by conductors including insulation.

FIG. 6B depicts an embodiment of a representation of a substrate 200 including insulation 230 positioned around conductors 100 between the core and conductors such that insulated conductors are positioned between conductors carrying different charges. In the depicted embodiment again conductor 100a may have a different net charge than conductor 100b; however, in this embodiment insulating material 230 surrounds only one of the conductors (100a) to inhibit short circuits. By insulating only one of conductors 100a and 100b as opposed to both a finer pitch may be attained because fewer openings are enlarged to accommodate the insulating material. A finer pitch may allow for better matching with, for example, bumps on a C4 chip.

FIG. 7 depicts an embodiment of a method 400 for forming a carrier substrate for an integrated circuit which inhibits degradation due to short circuits. In some embodiments, a method as described herein for forming a carrier substrate for an integrated circuit may include forming 410 a first plurality of openings extending from a first surface to a second surface of a core. The method may include applying 420 a first insulating material to the first or the second surface such that the first insulating material is positioned in the first plurality of openings. The method may include forming 430 a second plurality of openings in the first insulating material positioned in the first plurality of openings. A first diameter of the first openings may be greater than a second diameter of the second openings.

What is claimed is:

1. A carrier substrate for an integrated circuit, comprising:
a core comprising a first surface and a second surface substantially opposing the first surface;
a first plurality of openings extending from the first surface to the second surface of the core; and
a first insulating material applied to a surface of the first plurality of openings.

2. The substrate of claim 1, wherein the first plurality of openings comprise a first conductor extending through each of the first plurality of openings from the first surface to the second surface.

3. The substrate of claim 1, wherein the first insulating material is applied to the surface of the first plurality of openings using vacuum lamination.

4. The substrate of claim 1, wherein the first insulating material comprises a resin.

5. The substrate of claim 1, further comprising at least one layer of insulating material applied to the first and/or second surface.

6. The substrate of claim 5, further comprising a second plurality of openings extending through at least one of the layers of insulating material.

7. The substrate of claim 6, further comprising a second conductor extending through each of the second plurality of openings.

8. The substrate of claim 1, wherein the first plurality of openings are positioned between a third and a fourth set of openings extending from the first surface to the second surface of the core, wherein a third conductor extends through each of the third plurality of openings, wherein a fourth conductor extends through each of the fourth plurality of openings, and wherein the third and fourth conductors comprise a different charge.

9. The substrate of claim 1, wherein at least a first subset of the first plurality of openings comprise a first charge applied to a first conductor and at least a second subset of the first plurality of openings comprise a second charge applied to a second conductor, and wherein the first charge and the second charge are different.

10. A method for forming a carrier substrate for an integrated circuit, comprising:
forming a first plurality of openings extending from a first surface to a second surface of a core;
applying a first insulating material to the first or the second surface such that the first insulating material is positioned in the first plurality of openings; and
forming a second plurality of openings in the first insulating material positioned in the first plurality of openings, wherein a first diameter of the first openings is greater than a second diameter of the second openings.

11. The method of claim 9, wherein the first insulating material comprises a resin.

12. The method of claim 9, further comprising applying the first insulating material to the first or the second surface using vacuum lamination.

13. The method of claim 9, further comprising forming the second plurality of openings in the first insulating material positioned in the first plurality of openings such that the first insulating material coats a surface of the first plurality of openings.

14. The method of claim 9, wherein the first plurality of openings comprise a first conductor extending through each of the first plurality of openings from the first surface to the second surface.

15. The method of claim 9, further comprising applying at least one layer of a second insulating material to the first and/or second surface.

16. The method of claim 15, further comprising forming a third plurality of openings extending through at least one of the layers of insulating material.

17. The method of claim 16, further comprising forming a second conductor extending through each of the third plurality of openings.

18. The method of claim 9, wherein the first plurality of openings are positioned between a fourth and a fifth set of openings extending from the first surface to the second surface of the core, wherein a third conductor extends through each of the fourth plurality of openings, wherein a fourth conductor extends through each of the fifth plurality of openings, and wherein the third and fourth conductors comprise a different charge.

19. The method of claim 9, wherein at least a first subset of the first plurality of openings comprise a first charge applied to a first conductor and at least a second subset of the first plurality of openings comprise a second charge applied to a second conductor, and wherein the first charge and the second charge are different.

20. A carrier substrate for an integrated circuit, comprising:
a core comprising a first surface and a second surface substantially opposing the first surface;
a first plurality of openings extending from the first surface to the second surface of the core; and
a first insulating material applied to a surface of the first plurality of openings;
wherein at least a first subset of the first plurality of openings comprise a first charge applied to a first conductor and at least a second subset of the first plurality of openings comprise a second charge applied to a second conductor, wherein the first charge and the second charge are different, wherein the first subset are positioned between conductors comprising a first charge and conductors comprising a second charge, and wherein the second subset are positioned between conductors comprising a first charge and conductors comprising a second charge.
